(19) United States
(12) Patent Application Publication
(10) Pub. No.: US 2016/0079459 A1
(43) Pub. Date: Mar. 17, 2016

(54) SOLAR CELL MODULE

(71) Applicant: Panasonic Intellectual Property Management Co., Ltd., Osaka (JP)

(72) Inventor: Tomoki NARITA, Osaka (JP)

(21) Appl. No.: 14/946,215

(22) Filed: Nov. 19, 2015

Related U.S. Application Data
(63) Continuation of application No. PCT/JP2014/002734, filed on May 23, 2014.

(30) Foreign Application Priority Data
May 28, 2013 (JP) 2013-111739

(51) Int. Cl. H01L 31/05; H01L 31/0224

(52) U.S. Cl. CPC H01L 31/0516; H01L 31/0512; H01L 31/022441

(57) ABSTRACT

A solar cell module is provided with: a wiring material which electrically connects the light receiving surface-side electrode of the first solar cell with the rear surface-side electrode of the second solar cell; a first resin adhesive layer disposed between the wiring material and the light receiving surface-side electrode; and a second resin adhesive layer which is disposed between the wiring material and the rear surface-side electrode, and which has a smaller surface area than the first resin adhesive layer.

### CROSS REFERENCE TO RELATED APPLICATIONS

The present application is a continuation under 35 U.S.C. §120 of PCT/JP2014/002734, filed May 23, 2014, which is incorporated herein by reference and which claimed priority to Japanese Patent Application No. 2013-111739 filed on May 28, 2013. The present application likewise claims priority under 35 U.S.C. §119 to Japanese Patent Application No. 2013-111739 filed on May 28, 2013, the entire content of which is also incorporated herein by reference.

### BACKGROUND

1. Technical Field

The present invention relates to a solar cell module.

2. Related Art

A solar cell module has a plurality of solar cells. The plurality of the solar cells are electrically connected to each other by a wiring member.

The wiring member is in general adhered to the solar cell by solder. However, in the adhesion process using solder, the solar cell is heated to a high temperature. Because of this, due to a difference in the thermal expansion coefficient between the solar cell and the wiring member, a large thermal stress is applied to the solar cell.

In this regard, for example, JP 2012-253062 A proposes adhesion of the wiring member to the solar cell by a resin adhesive layer. According to this technique, the wiring member can be adhered to the solar cell at a temperature lower than that in the adhesion process by the solder. With such a configuration, the thermal stress applied to the solar cell can be reduced, and curling of the solar cell can be inhibited.

### RELATED ART REFERENCE

### Patent Document

### [Patent Document 1] JP 2012-253062 A

In a solar cell, an electrode on a light receiving surface side is desired to have a small area in order to prevent blockage of the entering light. Meanwhile, for the electrode on a back surface side, in order to reduce the surface resistance, it is desired to have a larger area than the electrode on the light receiving surface side. When a configuration is employed, in order to maximize the area of the electrode on the back surface side, in which the electrode on the back surface side has a thin film form, formed over approximately the entire back surface of the solar cell, the solar cell tends to be more easily curled because of a difference in the electrode area between the light receiving surface side and the back surface side.

Furthermore, in recent years, in order to reduce the manufacturing cost of the solar cell, it is desired to reduce the thickness of the solar cell. When the thickness of the solar cell is reduced, the solar cell tends to be more easily curled.

When the wiring member is adhered to the solar cell by a resin adhesive layer, a step of thermocompression bonding the wiring member on the solar cell is necessary. In this step, if the solar cell is curled, a large pressure would be applied to a part of the solar cell from the wiring member, resulting in a possibility of generation of a crack in the solar cell.

In addition, when a curling is caused in the solar cell in the solar cell module, there is a possibility that the resin adhesive layer will become partially detached from the solar cell as a result of to the curling, and that the wiring member and the solar cell will not be electrically connected with each other at that portion.

A primary advantage of the present invention is that a solar cell module is provided having a high endurance with respect to the curling of the solar cell.

### SUMMARY

According to one aspect of the present invention, there is provided a solar cell module comprising: a plurality of solar cells including a first solar cell and a second solar cell adjacent to the first solar cell. Each of the solar cells comprises: a photoelectric conversion unit; a light receiving surface side electrode placed over a part of a light receiving surface of the photoelectric conversion unit; and a thin film-form back surface side electrode formed to cover substantially the entire back surface of the photoelectric conversion unit. The solar cell module further comprises: a wiring member that electrically connects the light receiving surface side electrode of the first solar cell and the back surface side electrode of the second solar cell; a first resin adhesive layer placed between the wiring member and the light receiving surface side electrode; and a second resin adhesive layer placed between the wiring member and the back surface side electrode and having a smaller area than the first resin adhesive layer.

### Advantageous Effect

According to various aspects of the present invention, a solar cell module can be provided having a high endurance with respect to the curling of the solar cell.

### BRIEF DESCRIPTION OF THE DRAWINGS

FIG. 1 is a simplified plan view of a solar cell module according to a first preferred embodiment of the present invention.

FIG. 2 is a schematic cross sectional diagram of a part of a solar cell module according to a first preferred embodiment of the present invention, along an A-A line of FIG. 1.

FIG. 3 is a schematic cross sectional diagram of a part of a solar cell module according to a first preferred embodiment of the present invention, along a B-B line of FIG. 1.

FIG. 4 is a simplified plan view of a light receiving surface side of apart of a solar cell module according to a first preferred embodiment of the present invention.

FIG. 5 is a simplified plan view of a back surface side of a part of a solar cell module according to a first preferred embodiment of the present invention.

FIG. 6 is a simplified cross sectional diagram of a part of a solar cell module according to a second preferred embodiment of the present invention.

FIG. 7 is a simplified plan view of a back surface side of a part of a solar cell module according to a third preferred embodiment of the present invention.

FIG. 8 is a schematic cross sectional diagram of a part of a solar cell module according to a third preferred embodiment of the present invention, along a C-C line of FIG. 7.

FIG. 9 is a schematic cross sectional diagram of a part of a solar cell module according to a fourth preferred embodiment of the present invention.

FIG. 10 is a simplified plan view of a back surface side of a part of a solar cell module according to a fourth preferred embodiment of the present invention.

FIG. 11 is a simplified plan view of a back surface side of a solar cell module according to a fifth preferred embodiment of the present invention.

### DETAILED DESCRIPTION

Preferred embodiments of the present invention will now be described. The below-described embodiments are merely exemplary, and the present invention is not limited to the below-described embodiments in any way.

In the drawings, members having substantially the same function will be referred to with the same reference numerals. In addition, the drawings are schematically described, and a ratio of sizes of elements or the like drawn in the drawings may differ from the actual ratio of sizes of the elements or the like. Moreover, the size ratio of the elements or the like may differ among the drawings. The specific size ratio of the elements or the like should be determined with reference to the following description.

Before the details of the preferred embodiments are described, terms that should be particularly noted among the terms used in the present specification will be described.

In the present specification, a term “over” used in description of placement relationship of members is not intended to only mean a case where the elements are placed in direct contact with each other, and is rather intended to include cases where other members are interposed between the elements. For example, a description of “a second member is placed over a first member” not only includes a case where the first member and the second member are placed in direct contact with each other, but also includes a case where other members are interposed between the first member and the second member.

In the present specification, a “light receiving surface” refers to a primary surface, of the primary surfaces of the members, on a side on which light primarily enters from the outside of the solar cell module. For example, of the light entering the solar cell module, more than 50% and up to 100% enters from the light receiving surface side. A “back surface” refers to a primary surface, of the primary surfaces of the elements, on a side opposite to the light receiving surface.

In the present specification, an “x direction” and a “y direction” refer to directions parallel to the directions shown in the drawing with arrows. These terms are described in a plurality of drawings, and, among the drawings, these directions are related to each other.

### First Preferred Embodiment

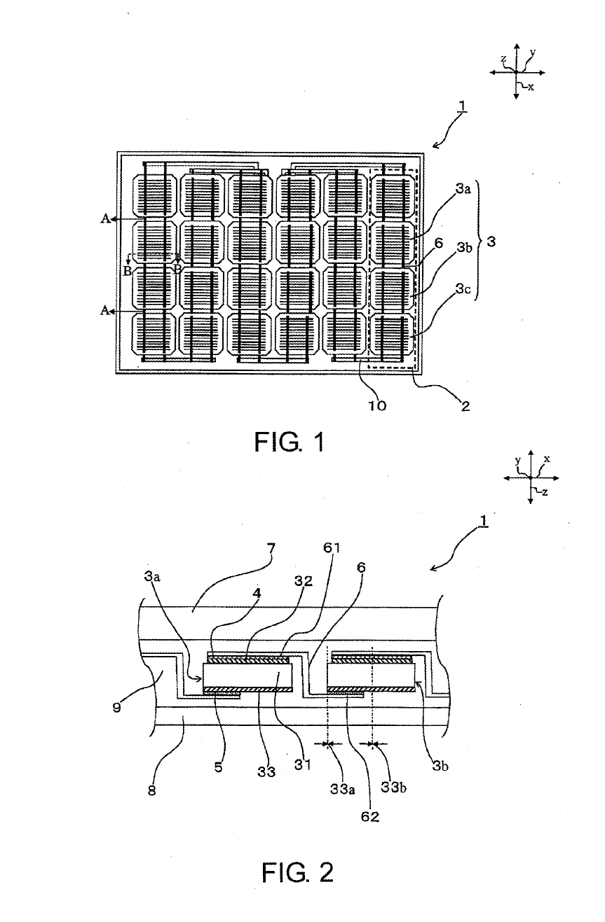

FIG. 1 is a simplified plan view of a solar cell module 1 according to a first preferred embodiment of the present invention.

The solar cell module 1 comprises a plurality of solar cells 3 arranged in an x direction and a y direction, a plurality of wiring members 6 extending with the x direction as a longitudinal direction, and a plurality of bridge wirings 10 placed at a periphery near an end in the x direction, among the peripheries of the solar cell module 1, and which extend along the y direction.

The plurality of solar cells 3 are electrically connected to each other by the plurality of wiring members 6 in one line along the x direction, to form a solar cell string 2. Specifically, one solar cell string 2 comprises a first solar cell 3a, and a second solar cell 3b which is adjacent to the first solar cell 3a along the x direction. The first and second solar cells 3a and 3b are electrically connected to each other by the wiring member 6. More specifically, the wiring member 6 is electrically connected to a light receiving surface of the first solar cell 3a, and is electrically connected to a back surface of the second solar cell 3b. This configuration is repeated at each solar cell 3, and in the solar cell string 2, the plurality of solar cells 3 are electrically connected to each other by the plurality of wiring members 6.

A plurality of solar cell strings 2 are electrically connected to each other by the bridge wiring 10. Specifically, the solar cell string 2 includes a solar cell 3c which is placed at a position nearest to the end in the x direction. The end solar cell 3c is placed near the bridge wiring 10, and is electrically connected by the wiring member 6 to the bridge wiring 10. This configuration is repeated at each solar cell string 2, and in one solar cell module 1, a plurality of solar cell strings 2 are electrically connected to each other through the bridge wirings 10.

As described, in one solar cell module 1, a plurality of the solar cells 3 are electrically connected to each other through the wiring member 6 and the bridge wiring 10.

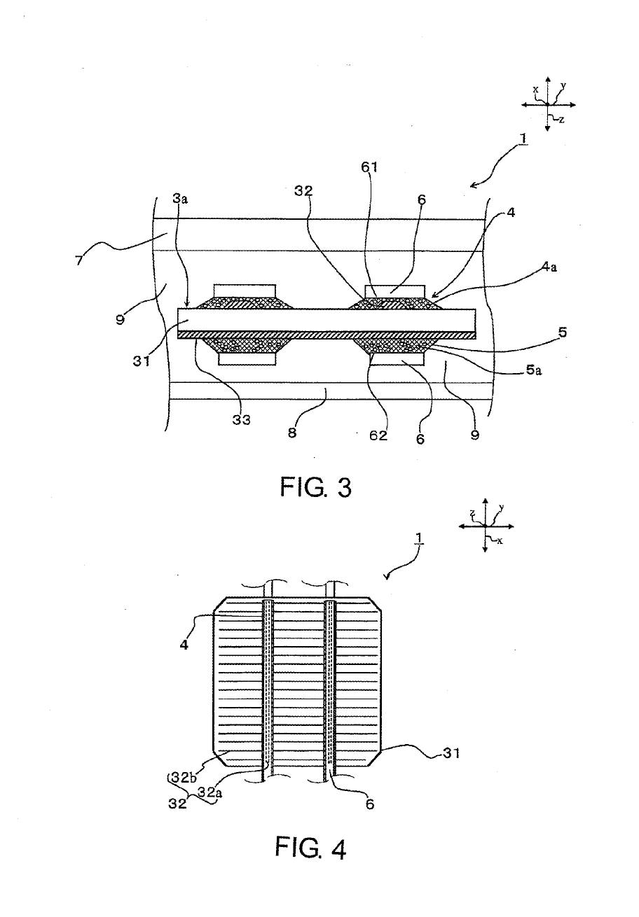

FIG. 2 is a schematic cross sectional diagram of the solar cell module 1 according to the first preferred embodiment of the present invention, along an A-A line of FIG. 1. FIG. 3 is a schematic cross sectional diagram of the solar cell module 1 according to the first preferred embodiment, along a B-B line of FIG. 1.

First, of the structures shown in the schematic cross sectional diagrams of FIGS. 2 and 3 of the solar cell module 1, a structure of a part also shown in the simplified plan view of FIG. 1 of the solar cell module 1 will be described in detail.

The solar cell module 1 comprises a first solar cell 3a, a second solar cell 3b which is adjacent to the first solar cell 3a along the x direction, a wiring member 6 placed to extend from a region over the light receiving surface of the first solar cell 3a to a region over the back surface of the second solar cell 3b, a first resin adhesive layer 4 placed between the light receiving surface of the first solar cell 3a and the wiring member 6, and a second resin adhesive layer 5 placed between the back surface of the second solar cell 3b and the wiring member 6.

Each of the first and second solar cells 3a and 3b includes a photoelectric conversion unit 31, a light receiving surface side electrode 32 placed over the light receiving surface of the photoelectric conversion unit 31, and aback surface side electrode 33 placed over the back surface of the photoelectric conversion unit 31.

The photoelectric conversion unit 31 is a member which absorbs incident light and generates a photovoltaic force. The structure of the photoelectric conversion unit 31 is not particularly limited, and for example, the photoelectric conversion unit 31 may have a structure in which an i-type amorphous silicon layer, a p-type amorphous silicon layer doped with boron (B) or the like, and a transparent conductive film are formed in this order over the light receiving surface side of an n-type monocrystalline silicon substrate, and an i-type amorphous silicon layer, an n-type amorphous silicon layer doped with phosphorus (P) or the like, and a transparent conductive film are formed in this order over the back surface side of the substrate.

The light receiving surface side electrode 32 is placed over a part of the light receiving surface of the photoelectric conversion unit 31. The light receiving surface side electrode 32 is placed to expose a part of the light receiving surface of the photoelectric conversion unit 31 so as to not block the light entering the photoelectric conversion unit 31 from the light receiving surface side. The light receiving surface side electrode 32 may be formed, for example, from at least one metal such as Ag and Cu.

The back surface side electrode 33 is placed over the back surface of the photoelectric conversion unit 31. The back surface side electrode 33 is formed to have a larger area than the light receiving surface side electrode. Specifically, the back surface side electrode 33 is formed by a thin film surface-form electrode covering substantially the entire back surface of the photoelectric conversion unit 31 to such a degree that the light does not enter the photoelectric conversion unit 31 from the back surface side. With such a configuration, the light entering from the back surface side is blocked by the back surface side electrode 33, but the surface resistance of the back surface side electrode 33 can be reduced, and as a result, an output of the solar cell module can be improved. The back surface side electrode 33 comprises, for example, a copper (Cu) electrode layer, and a tin (Sn) electrode or a nickel copper (CuNi) layer provided over the copper electrode layer and having approximately the same area as the copper electrode layer.

The wiring member 6 is placed to be connected to the light receiving surface side electrode 32 of the first solar cell 3a, and to be connected to the back surface side electrode 33 of the second solar cell 3b. The wiring member 6 is an elongated metal foil with the x direction as the longitudinal direction, and has at least a length to allow connection of the light receiving surface side electrode 32 of the first solar cell 3a and the back surface side electrode 33 of the second solar cell 3b. The wiring member 6 is obtained, for example, by plastic-working a silver-plated copper line or an aluminum line. A width of the wiring member 6 in the transverse direction (y direction) is the same along the longitudinal direction (x direction).

The wiring member 6 comprises a first surface region 61 opposing the light receiving surface side electrode 32 and a second surface region 62 opposing the back surface side electrode 33. The wiring member 6 is placed such that the second surface region 62 has a smaller area than the first surface region 61. In the present embodiment, a width of the wiring member 6 in the transverse direction (y direction) is the same along the longitudinal direction (x direction). Therefore, the widths of the first surface region 61 and the second surface region 62 in the transverse direction (y direction) are also approximately the same. Thus, the wiring member 6 is placed such that a length of the second surface region 62 in the longitudinal direction (x direction) is shorter than a length of the first surface region 61 in the longitudinal direction (x direction). More specifically, the first surface region 61 has a length in the longitudinal direction (x direction) so as to extend from one end of the light receiving surface side electrode 32 to the other end, while the second surface region 62 has a length in the longitudinal direction (x direction) which is shorter than the length in the longitudinal direction (x direction) of the first surface region 61. The length of the second surface region 62 in the longitudinal direction (x direction) can be suitably shortened based on a value of the surface resistance of the back surface side electrode 33. For example, when the surface resistance of the back surface side electrode 33 is 0.05Ω/□, the length of the second surface region 62 in the longitudinal direction (x direction) may be about 0.9 times the length of the first surface region 61 in the longitudinal direction (x direction), and when the surface resistance of the back surface side electrode 33 is 0.01Ω/□, the length of the second surface region 62 in the longitudinal direction (x direction) may be about 0.6 times the length of the first surface region 61 in the longitudinal direction (x direction). In addition, for example, by forming the back surface side electrode 33 in a thick thickness using a copper paste, the surface resistance of the back surface side electrode 33 can be further reduced. In this case, as shown in the example configuration of FIG. 2, it is possible to employ a length of the second surface region 62 in the longitudinal direction (x direction), such that the second surface region 62 extends from one end 33a of the back surface side electrode 33 and does not reach a center region 33b.

The first resin adhesive layer 4 is placed including a region between the light receiving surface side electrode 32 of the first solar cell 3a and the first surface region 61 of the wiring member 6. The first resin adhesive layer 4 has a function to adhere the light receiving surface side electrode 32 and the wiring member 6, and for example, an adhering and thermosetting resin material is used, such as an epoxy resin, an acrylic resin, a urethane resin, or the like. The first resin adhesive layer 4 may be formed from only an insulating resin material, or may be given electrical conductivity by dispersing conductive particles 4a (not shown in FIG. 2) in a resin material.

The second resin adhesive layer 5 is placed between the back surface side electrode 33 of the second solar cell 3b and the second surface region 62 of the wiring member 6. The second resin adhesive layer 5 has a function to adhere the back surface side electrode 33 and the wiring member 6, and similar to the first resin adhesive layer 4, for example, an adhering and thermosetting resin material is used, such as the epoxy resin, the acrylic resin, the urethane resin, or the like. The second resin adhesive layer 5 may be formed from only an insulating resin material, or may be given electrical conductivity by dispersing conductive particles 5a (not shown in FIG. 2) or the like in a resin material. The second resin adhesive layer 5 may be formed from a material similar to that of the first resin adhesive layer 4, or from a different material.

The second resin adhesive layer 5 is placed to have a smaller area than that of the first resin adhesive layer 4. Specifically, the second resin adhesive layer 5 is placed to have a smaller adhesion area with the wiring member 6 than the first resin adhesive layer 4. As a specific structure for realizing this configuration, in the present embodiment, widths of the first and second resin adhesive layers 4 and 5 in the transverse direction (y direction) are set equal to each other, the first resin adhesive layer 4 is placed between the light receiving surface side electrode 32 and the first surface region 61 of the wiring member 6, and the second resin adhesive layer 5 is placed between the back surface side electrode 33 and the second surface region 62 of the wiring member 6. As described above, the wiring member 6 is placed to have a smaller area of the second surface region 62 than the first surface region 61. The first resin adhesive layer 4 is placed between the first surface region 61 of the wiring member 6 and the light receiving surface side electrode 32, and the second resin adhesive layer 5 is placed between the second surface region 62 of the wiring member 6 and the back surface side electrode 33. With this configuration, according to a difference in length in the longitudinal direction (x direction) between the first and second surface regions 61 and 62 of the wiring member 6, the length of the second resin adhesive layer 5 in the longitudinal direction (x direction) would be shorter than the length of the first resin adhesive layer 4 in the longitudinal direction (x direction). As a result, the area of the second resin adhesive layer 5 becomes smaller than the area of the first resin adhesive layer 4 according to the difference in the length in the longitudinal direction (x direction) between the first and second resin adhesive layers 4 and 5.

When the area of the back surface side electrode 33 is smaller than the area of the light receiving surface side electrode 32, a stress difference is caused between the light receiving surface and the back surface of the solar cell 3 depending on the area difference, and the solar cell 3 tends to be more easily curled. However, by setting the area of the second resin adhesive layer 5 to be smaller than the area of the first resin adhesive layer 4, the curling of the solar cell 3 can be reduced. For example, the second resin adhesive layer 5 is set to have an area of about 0.6-0.9 times the area of the first resin adhesive layer 4. With such a configuration, the curling of the solar cell 3 can be reduced while not increasing the resistive loss of the solar cell 3.

Next, of the structures shown in the schematic cross sectional diagrams of FIGS. 2 and 3 of the solar cell module 1, structures of a part not shown in the schematic plan view of FIG. 1 of the solar cell module 1 will be primarily described in detail.

The solar cell module 1 further comprises a light receiving surface side protection component 7 placed on the light receiving surface side of the plurality of solar cells 3, a back surface side protection component 8 placed on the back surface side of the plurality of solar cells 3, and a sealing member 9 placed between the protection components 7 and 8 and which seals the plurality of solar cells 3.

The light receiving surface side protection component 7 is provided on the light receiving surface side of the solar cell 3, protects the solar cell 3 from the external environment, and allows light of a wavelength band absorbed by the solar cell 3 for power generation to pass through. The light receiving surface side protection component 7 may be formed, for example, from a glass plate, a ceramic plate, a resin plate, or the like.

The back surface side protection component 8 may be formed, for example, from a resin sheet, a resin sheet including a barrier layer made of a metal or an inorganic oxide, a glass plate, a resin plate, or the like.

The sealing member 9 may be formed, for example, from an ethylene vinyl acetate copolymer (EVA), polyolefin, or the like. The sealing member 9 may be formed in different forms between the light receiving surface side and the back surface side of the plurality of solar cells 3. For example, a part of the sealing member 9 positioned on the back surface side of the plurality of solar cells 3 may include a pigment or a colorant that reflects infrared rays, so that the infrared rays transmitting through the plurality of solar cells 3 can be reflected toward the side of the plurality of solar cells 3 by the sealing member 9. As a pigment that reflects the infrared rays, titanium oxide may be exemplified.

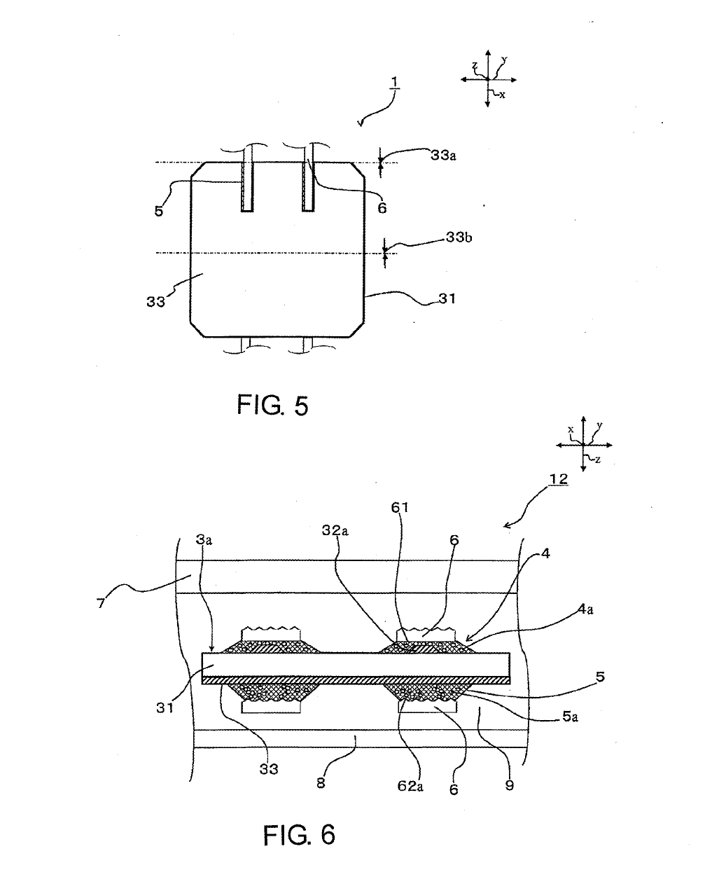

Next, with reference to FIGS. 4 and 5, of the structures of the light receiving surface side and back surface side electrodes 32 and 33, the first and second resin adhesive layers 4 and 5, and the wiring member 6, structures that can be understood from the plan view will be described in detail.

FIG. 4 is a simplified plan view of a light receiving surface side of a part of the solar cell module 1 according to the first preferred embodiment of the present invention.

The light receiving surface side electrode 32 is placed to expose a part of the light receiving surface of the photoelectric conversion unit 31 so as to not block light entering the photoelectric conversion unit 31 from the light receiving surface side. The light receiving surface side electrode 32 comprises a plurality of bus bar electrodes 32a placed at a position overlapping the wiring member 6, and a plurality of finger electrodes 32b placed to be connected to the plurality of bus bar electrode 32a.

Each of the plurality of bus bar electrodes 32a has a shape extending from one end to the other end on the light receiving surface of the photoelectric conversion unit 31 along the x direction, so as to be adhered to the wiring member 6. Here, it is only necessary for the bus bar electrode 32a as a whole to extend along the x direction. In other words, the bus bar electrode 32a is not limited to a structure extending in a straight line shape parallel to the x direction, and may have, for example, a shape extending in a zigzag shape in which a plurality of straight lines not parallel to the x direction are connected to each other. The plurality of bus bar electrodes 32a are placed with a gap therebetween along the y axis direction. The bus bar electrode 32a is desirably formed in a narrow shape to such a degree that does not block the light entering the photoelectric conversion unit 31, and sufficiently wide to allow efficient flow of electric power collected from the plurality of finger electrodes 32b.

Each of the plurality of finger electrodes 32b has a shape connected to the bus bar electrode 32a and extending along the y axis direction. The plurality of finger electrodes 32b are placed with a gap therebetween along the x axis direction. The finger electrode 32b is desirably formed narrow to not block the light entering the photoelectric conversion unit 31. In addition, the finger electrode 32b is desirably placed with a predetermined spacing in order to allow efficient collection of the generated electric power.

The first resin adhesive layer 4 is applied extending from one side to the other side of the bus bar electrode 32a along the x direction so as to cover the entirety of the bus bar electrode 32a.

The wiring member 6 is placed over the first resin adhesive layer 4, and is adhered to the bus bar electrode 32a. The wiring member 6 is placed to extend from one end to the other end of the first resin adhesive layer 4 along the x direction.

FIG. 5 is a simplified plan view of the back surface side of a part of the solar cell module 1 according to the first preferred embodiment of the present invention.

The back surface side electrode 33 is placed to cover substantially the entire back surface of the photoelectric conversion unit 31 to such a degree that the light does not enter the photoelectric conversion unit 31 from the back surface side, in order to increase the area to an area larger than the light receiving surface side electrode 32. With such a configuration, the light entering from the back surface side of the solar cell module 1 is blocked by the back surface side electrode 33, but the surface resistance of the back surface side electrode 33 is reduced, and as a consequence, the output of the solar cell module 1 is improved.

The second resin adhesive layer 5 is applied in a manner to be shorter along the x direction than the first resin adhesive layer 4 over a part of the aback surface side electrode 33. In the present embodiment, the first and second resin adhesive layers 4 and 5 have the same width. Therefore, the second resin adhesive layer 5 is applied having a smaller area than the area of the first resin adhesive layer 4.

The wiring member 6 is placed over the second resin adhesive layer 5 and is adhered to the back surface side electrode 33. The wiring member 6 is placed to extend from one end to the other end of the second resin adhesive layer 5 along the x direction, in accordance with the length of the second resin adhesive layer 5. In this configuration, the length in the longitudinal direction (x direction) of the second surface region 62 of the wiring member 6 opposing the back surface side electrode 33 is shorter than the length in the longitudinal direction (x direction) of the first surface region 61 of the wiring member 6 opposing the light receiving surface side electrode 32. In the present embodiment, the wiring member 6 has an approximately the same width in the first and second surface regions 61 and 62. Therefore, the wiring member 6 is placed over the first and second resin adhesive layers 4 and 5 such that the second surface region 62 has a smaller area than the first surface region 61.

As described, in the solar cell module 1 according to the present embodiment, the solar cell 3 has a thin film surface-form back surface side electrode 33 having a larger area than the light receiving surface side electrode 32. According to such a configuration, the difference in area between the light receiving surface side electrode 32 and the back surface side electrode 33 is large, and the solar cell 3 tends to be easily curled. However, the second resin adhesive layer 5 placed between the wiring member 6 and the back surface side electrode 33 is applied having a smaller area than the first resin adhesive layer 4 placed between the wiring member 6 and the light receiving surface side. With such a configuration, the adhesion area between the wiring member 6 and the back surface side electrode 33 is smaller than the adhesion area between the wiring member 6 and the light receiving surface side electrode 32. A stress generated as result of a difference between the adhesion area between the wiring member 6 and the back surface side electrode 33 and the adhesion area between the wiring member 6 and the light receiving surface side electrode 32 acts in a direction opposite to the stress depending on the area difference between the light receiving surface side electrode 32 and the back surface side electrode 33. Because of this, the curling of the solar cell 1 is reduced.

In addition, in the solar cell module 1 according to the present embodiment, the wiring member 6 is placed to have a smaller area of the second surface region 62 opposing the back surface side electrode 33 than the area of the first surface region 61 opposing the light receiving surface side electrode 32. Because of this, a material cost of the wiring member 6 can be reduced in accordance with the area of the second surface region 62 of the wiring member 6. Moreover, the wiring member 6 is heated to a high temperature in a step of adhesion to the solar cell 3. Therefore, when the temperature returns to room temperature after this step, the wiring member 6 shrinks, and stress is caused in the solar cell 3. However, by setting the area of the second surface region of the wiring member 6 to be small, the stress generated in the solar cell 3 can be reduced.

An example manufacturing method of the solar cell module 1 will now be described.

First, on each of the light receiving surface and the back surface of the photoelectric conversion unit 31, the light receiving surface side and back surface side electrodes 32 and 33 are formed, to complete the solar cell 3. The light receiving surface side electrode 32 may be formed by, for example, applying a conducive paste using screen printing. In this case, the conductive paste is applied according to pattern shapes of the bus bar electrode 32a and the finger electrode 32b described above. The back surface side electrode 33 can be formed, for example, by applying copper over substantially the entire back surface of the photoelectric conversion unit 31 by sputtering, and applying tin or copper-nickel over the copper. Alternatively, the light receiving surface side and back surface side electrodes 32 and 33 may be formed by other application methods such as plating, CVD, or the like.

Next, the first resin adhesive layer 4 is applied along the bus bar electrode 32a, of the light receiving surface side electrode 32. The first resin adhesive layer 4 is applied by applying a paste-form resin adhesive using an application means such as a dispenser and screen printing. The first resin adhesive layer 4 is, for example, a paste-form resin formed by mixing a solid composition into an epoxy resin to which a curing agent is added. Alternatively, the first resin adhesive layer 4 may be applied by affixing a film-form layer over the bus bar electrode 32a.

Then, the second resin adhesive layer 5 is applied over the back surface side electrode 33. The application method may be realized by a method similar to that for the light receiving surface side electrode 32. However, over the back surface side electrode 33, the second resin adhesive layer 5 is applied to be shorter than the first resin adhesive layer 4. For example, the length of the second resin adhesive layer 5 is preferably shorter, and about 0.6-0.9 times that of the first resin adhesive layer 4.

Next, the wiring member 6 is placed over the first resin adhesive layer 4, and the wiring member 6 and the bus bar electrode 32a are thermocompression-bonded, to adhere the wiring member 6 and the bus bar electrode 32a. Similarly, the wiring member 6 is placed over the second resin adhesive layer 5, and the wiring member and the back surface side electrode 33 are thermocompression-bonded, to adhere the wiring member 6 and the back surface side electrode 33. In this process, the wiring member 6 is placed such that the second surface region 62 opposing the electrode on the back surface side has a shorter length in the longitudinal direction (x direction) than the first surface region 61 opposing the light receiving surface side electrode 32. For example, the length of the second surface region 62 is preferably shorter and is 0.6-0.9 times the length of the first surface region 61.

Then, the light receiving surface side protection component 7, a resin sheet for forming the sealing member 9, the solar cell 3, a resin sheet for forming the sealing member 9, and the back surface side protection component 8 are layered in this order. By laminating the obtained multilayer structure, the solar cell module 1 is completed.

In the following, other preferred configurations of the present invention will be described. In the following description, members having substantially common functions to those in the first preferred embodiment are assigned common reference numerals, and will not be described again.

### Second Preferred Embodiment

In the first embodiment, an example configuration which uses a flat plate-shaped wiring member 6 has been described. However, the present invention is not limited to such a configuration.

FIG. 6 is a simplified cross sectional diagram of a part of a solar cell module 12 according to a second preferred embodiment of the present invention.

In the solar cell module 12 according to the second preferred embodiment, the wiring member 6 has an uneven surface 62a only on the same surface side as the second surface region 62 opposing the back surface side electrode 33, and has a flat surface on the same surface side as the first surface region 61 opposing the light receiving surface side electrode 32. Using such a wiring member 6, the wiring member 6 is placed such that the back surface side electrode 33 and the uneven surface 62a of the second surface region 62 oppose each other, and the bus bar electrode 32a and the flat surface of the first surface region 61 oppose each other. By employing such a configuration, it is possible to allow the light, of the light entering from the light receiving surface side, entering the wiring member 6, to re-enter the light receiving surface of the solar cell 3. In addition, in the wiring member 6, a larger amount of the second resin adhesive layer 5 would be placed in the recess portion of the uneven surface 62a, and consequently, the adhesion strength per unit area of the wiring member 6 with the back surface side electrode 33 can be improved. Because of this, even when the length of the second surface region 2 of the wiring member 6 placed over the back surface side electrode 33 is shortened, a sufficient adhesion can be achieved.

### Third Preferred Embodiment

In the first embodiment, an example configuration has been described in which the second resin adhesive layer 5 is placed only over the back surface side electrode 33. The present invention, however, is not limited to such a configuration.

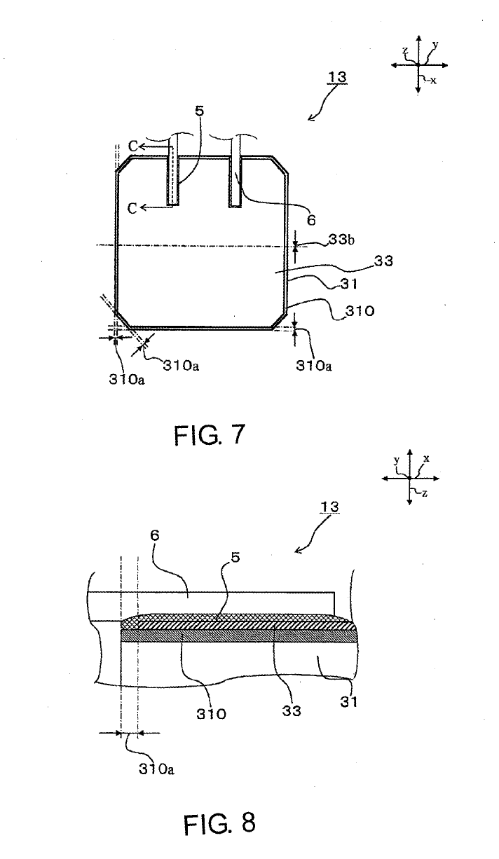

FIG. 7 is a simplified plan view of a back surface side of a part of a solar cell module 13 according to a third preferred embodiment of the present invention. FIG. 8 is a schematic cross sectional diagram of a part of the solar cell module 13 according to the third preferred embodiment, along a C-C line in FIG. 7.

The solar cell module 13 according to the third preferred embodiment comprises a photoelectric conversion unit 31 having a transparent conductive film 310 formed over the back surface, a back surface side electrode 33 placed over the transparent conductive film 310, a second resin adhesive layer 5 placed over the transparent conductive film 310 and the back surface side electrode 33, and a wiring member 6 placed over the second resin adhesive layer 5.

The photoelectric conversion unit 31 has the transparent conductive film 310 over substantially the entire back surface. The transparent conductive film 310 is formed, for example, from indium oxide and zinc oxide having a metal dopant. As the metal dopant, for example, in the case of indium oxide, tungsten, tin, or the like is preferably used, and in the case of zinc oxide, gallium, aluminum, or the like is preferably used. The transparent conductive film 310 may include crystals. In other words, the transparent conductive film 310 may be formed by a polycrystalline layer or a monocrystalline layer of indium oxide or zinc oxide including a metal dopant. Alternatively, the transparent conductive film 310 may be formed from indium oxide or zinc oxide which does not include a metal dopant, but includes hydrogen.

The back surface side electrode 33 is placed to cover substantially the entire transparent conductive film 310 except for a periphery portion 310a of the transparent conductive film 310. With such a configuration, the periphery portion 310a of the transparent conductive film 310 is exposed from the back surface side electrode 33.

The second resin adhesive layer 5 is placed to extend from a region over the transparent conductive film 310 to a region over the back surface side electrode 33 of a portion adjacent the solar cell 3a, of the periphery portion 310a of the transparent conductive film 310. The second resin adhesive layer 5 is placed to be shorter than the first resin adhesive layer 4.

The wiring member 6 is placed over the second resin adhesive layer 5, and is adhered to the transparent conductive film 310 and the back surface side electrode 33. The second surface region 62 of the wiring member 6 is placed to be shorter than the first surface region 61 of the wiring member 6, similar to the second resin adhesive layer 5.

Because of this, in the periphery portion 310a of the transparent conductive film 310, the wiring member 6 is directly adhered to the transparent conductive film 310, and not through the back surface side electrode 33. With such a configuration, the wiring member 6 is bent toward the side of the transparent conducive film by a step at an end of the back surface side electrode 33, and it becomes more difficult for the wiring member 6 to be detached from the back surface side electrode 33.

### Fourth Preferred Embodiment

In the first embodiment, an example configuration has been described in which the wiring member 6 has a shorter length in the longitudinal direction (x direction) of the second surface region 62 opposing the back surface side electrode 33 than the length in the longitudinal direction (x direction) of the first surface region 61 opposing the front surface side electrode. The present invention, however, is not limited to such a configuration.

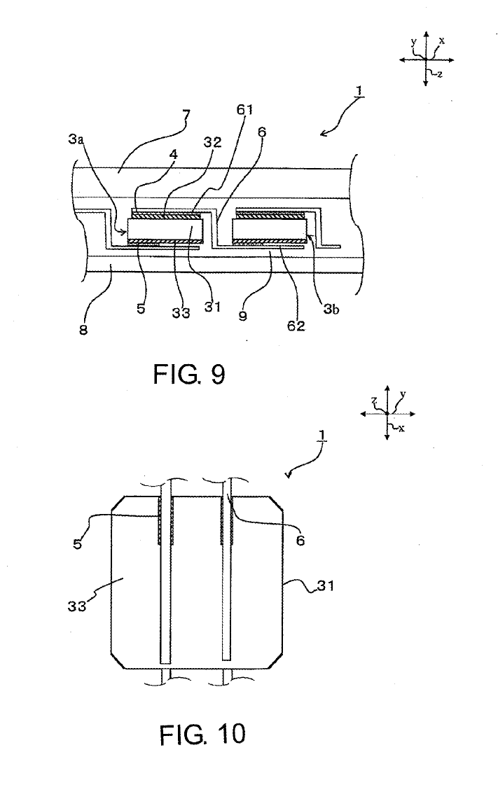

FIG. 9 is a schematic cross sectional diagram of a part of a solar cell module according to the fourth preferred embodiment of the present invention. FIG. 10 is a simplified plan view of the back surface side of a part of the solar cell module according to the fourth preferred embodiment.

Even when the lengths in the longitudinal direction (x direction) of the first and second surface regions 61 and 62 of the wiring member 6 are equal to each other, by changing the areas of the first and second resin adhesive layers 4 and 5, it is possible to set the adhesion area between the second surface region 62 of the wiring member 6 and the back surface side electrode 33 to be smaller than the adhesion area between the first surface region 61 of the wiring member 6 and the light receiving surface side electrode 32.

### Fifth Preferred Embodiment

In the first embodiment, an example configuration has been described in which the widths of the first and second resin adhesive layers 4 and 5 are equal to each other. The present invention, however, is not limited to such a configuration.

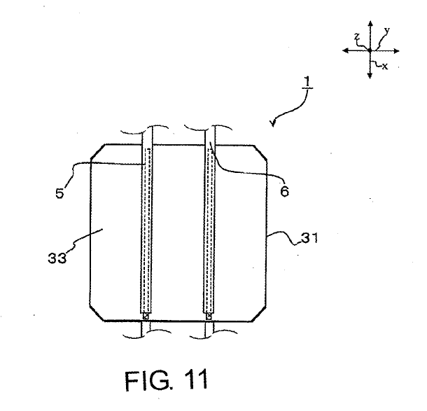

FIG. 11 is a simplified plan view of the back surface side of a part of a solar cell module according to the fifth preferred embodiment of the present invention.

It is possible to set the width of the second resin adhesive layer 5 to be smaller than the width of the first resin adhesive layer 4. In this case, even when the lengths in the longitudinal direction (x direction) of the first and second resin adhesive layers 4 and 5 are identical to each other, it is possible to set the adhesion area between the second surface region 62 of the wiring member 6 and the back surface side electrode 33 to be smaller than the adhesion area between the first surface region 61 of the wiring member 6 and the light receiving surface side electrode 32.

The present invention includes embodiments other than those described above, which are within the scope and spirit of the present invention. The embodiments are merely for explaining the invention, and do not limit the invention. The scope of the invention is described in the claims, and is not shown in the description of the specification. Therefore, the invention includes all forms including a meaning and scope within the range of equivalence of the claims.

### EXPLANATION OF REFERENCE NUMERALS

1 SOLAR CELL MODULE; 2 SOLAR CELL STRING; 3 SOLAR CELL; 3a FIRST SOLAR CELL; 3b SECOND SOLAR CELL; 3c END SOLAR CELL; 31 PHOTOELECTRIC CONVERSION UNIT; 310 TRANSPARENT CONDUCTIVE FILM; 310a PERIPHERY PORTION; 32 LIGHT RECEIVING SURFACE SIDE ELECTRODE; 32a BUS BAR ELECTRODE; 32b FINGER ELECTRODE; 33 BACK SURFACE SIDE ELECTRODE; 33a ONE END; 33b CENTER REGION; 4 FIRST RESIN ADHESIVE LAYER; 4 SECOND RESIN ADHESIVE LAYER; 5a CONDUCTIVE PARTICLE; 6 WIRING MEMBER; 61 FIRST SURFACE REGION; 62 SECOND SURFACE REGION; 62a UNEVEN SURFACE; 7 LIGHT RECEIVING SURFACE SIDE PROTECTION COMPONENT; 8 BACK SURFACE SIDE PROTECTION COMPONENT; 9 SEALING MEMBER; 10 BRIDGE WIRING.

What is claimed is:

1. A solar cell module comprising:
a plurality of solar cells including a first solar cell and a second solar cell adjacent to the first solar cell, wherein
each of the plurality of solar cells comprises:
a photoelectric conversion unit;
a light receiving surface side electrode placed over a part of a light receiving surface of the photoelectric conversion unit; and
a thin film-form back surface side electrode formed to cover substantially an entire back surface of the photoelectric conversion unit, and
a thin film-form back surface side electrode formed to cover substantially an entire back surface of the photoelectric conversion unit, and
the solar cell module further comprises:
a wiring member that electrically connects the light receiving surface side electrode of the first solar cell and the back surface side electrode of the second solar cell;
a first resin adhesive layer placed between the wiring member and the light receiving surface side electrode; and
a second resin adhesive layer placed between the wiring member and the back surface side electrode and having a smaller area than the first resin adhesive layer.

2. The solar cell module according to claim 1, wherein
the wiring member comprises:
a first surface region that opposes the light receiving surface side electrode; and
a second surface region that opposes the back surface side electrode and that is placed to have a smaller area than the first surface region.

3. The solar cell module according to claim 1, wherein the second surface region of the wiring member has an uneven surface having a larger step compared to the first surface region.

4. The solar cell according to claim 1, wherein
the photoelectric conversion unit further comprises a transparent conductive film covering substantially the entire back surface, and
the back surface side electrode is placed to expose a periphery portion of the transparent conductive film.

5. The solar cell module according to claim 4, wherein the second resin adhesive layer is placed to adhere the transparent conductive film and the wiring member at the periphery portion of the transparent conductive film.

6. The solar cell module according to claim 1, wherein at least one of the first and second resin adhesive layers has conductive particles.

7. The solar cell module according to claim 1, wherein
the light receiving surface side electrode comprises:
a bus bar electrode that extends along an arrangement direction of the first solar cell and the second solar cell; and
a plurality of finger electrodes that extend in a direction orthogonal to the arrangement direction and that are connected to the bus bar electrode, and
the first resin adhesive layer is placed between the bus bar electrode and the wiring layer.
